(19) United States
(12) Patent Application Publication
(10) Pub. No.: US 2004/0140469 A1
(43) Pub. Date: Jul. 22, 2004

(54) Panel of a flat display and method of fabricating the panel

(76) Inventors: Tsung-Neng Liao, Shen-Kang Hsiang (TW); Yuan-Tung Dai, Chung-Li City (TW); Chun-Chi Lee, Taipei (TW)

Correspondence Address: DELLETT AND WALTERS, P. O. BOX 2786, PORTLAND, OR, 97208-2786, US

(21) Appl. No.: 10/346,703

(22) Filed: Jan. 17, 2003

(51) Int. Cl. H01L 29/04; H01L 31/036; G02F 1/136

(52) U.S. Cl. 257/72; 257/59; 349/43; 349/42

(57) ABSTRACT

A panel is implemented by a method from bottom to top includes a display panel, an optical element film formed on the display panel and a semiconductor element film formed on the optical element film. The method discloses that the semiconductor element film is first formed on a temporary substrate and then the optical element film is further formed on the semiconductor element film. When the display panel is bonded on the optical element film the temporary substrate is removed from the semiconductor element film. Therefore, the semiconductor element film and the optical element film are integrated the same display panel.

### BACKGROUND OF THE INVENTION

1. Field of the Invention

The present invention relates to a panel of a flat display and a method of fabricating the panel, and more specifically to a panel of a flat display having a high display quality.

2. Description of Related Art

A conventional low temperature method adapted to fabricate semiconductor elements as thin film transistors (TFT) on a glass panel includes steps of depositing an amorphous silicon film on a top face of the glass panel, transforming the amorphous silicon film to a poly-silicon film by Excimer Laser Annealing (ELA) and fabricating TFTs on the poly-silicon film. The low temperature method can fabricating TFTs on the glass panel, but the electronic quality of the TFTs on the poly-silicon film is not good because the poly-silicon film has a small diameter crystalline grain. Consequently, the TFTs have a leakage current fault that affects the display quality of the TFT plane.

To overcome the leakage current fault with the low temperature fabricating method, a completely new fabricating method that uses a bonding technique has been proposed. With reference to FIGS. 5A to 5D, a portion of the panel of the flat display is fabricated by the new fabricating method. A TFT panel is an example of the plane of the flat display to introduce the method having the following steps.

In FIG. 5A, a first temporary substrate (50) suitable for fabricating good quality thin film transistors (TFTs) is prepared, and then a TFT film (51) is formed on the first temporary substrate (50). A fabricating TFT film (51) includes the following steps of

(a) forming a buffer layer (501) on the first substrate (50);

(b) forming semiconductor films (512) on the buffer layer (501), wherein each semiconductor film (512) is used to define a drain, source and an active region;

(c) forming a transparent insulating layer (513) on the semiconductor films (512) and the buffer layer (501), wherein portions of transparent insulating layer (513) on the semiconductor films (512) are gate oxide layers (513a);

(d) forming a first metal layer as a gate electrodes (514) on the portions of each gate oxide layers (513a) to complete a thin film transistor (TFT) (511), wherein the first metal layer is also a scan line;

(g) forming a inner layer (515) on the gate electrodes (514) and first transparent insulating layer (513), wherein second metal layers (516) are formed on the inner layer (515) for connecting the semiconductor layer (512);

(h) forming a protective film (517) on the second metal layer (516) and the inner layer (515);

(i) forming pixel electrodes (518) on the protective film (517), wherein each pixel electrode (518) is connected to TFT through the second metal layers (516).

Consequently, the TFT film (51) is from bottom to top composed of transistors (511), scan lines (514), data lines (516) and pixel electrodes (518), wherein the pixel electrodes (518) are on top of the TFT film (51).

In FIG. 5B, a second temporary substrate (60) is bonded on the top of the TFT film (51) to support the TFT film (51).

In FIG. 5C, the first temporary substrate (50) is removed and replaced with a display panel (70).

In FIG. 5D, the second temporary substrate (not shown) is removed from the top of the TFT film (51) to complete a TFT panel (70).

The TFT film (51) as described is first fabricated on the first temporary substrate (50) with good electronic characteristics. For example, the semiconductor as TFT fabricated on a Si-substrate is better than a TFT fabricated on a plastic or glass substrate. Therefore, the forgoing method introduces a method in which a good semiconductor as a TFT is first fabricated on the specific material substrate and then is transferred to the display panel, such as a plastic or glass panel, by a bonding technique. Therefore, the display panel has highly reliable TFTs to increase display quality. However, this method using a bonding technique still has the following faults:

1. The method uses at least two temporary substrates to form semiconductor elements (TFTs) on a display panel, so that the method has many complex steps.

2. The method can only fabricate semiconductor element film on a display panel but cannot fabricate the optical element film on the same display panel. The optical element film has to be fabricated on another panel. When fabricating a complete flat display, the panel with the semiconductor element film and the optical element panel must be accurately aligned when combined to ensure display quality. Therefore, the aligning step also affects the display quality.

3. The pixel electrodes of the semiconductor element film fabricated by the method have a rough exposed face that affects display quality. For example, during the forgoing fabricating TFT film process, many layers, such as the semiconductor films, the gate electrodes the first and second metal layers, are subjected to development and etching so the layers do not have a flat top faces. Specifically, the top layer of the TFT film obviously has rough top face. The top layer is the pixel electrode. Therefore, the exposed rough faces of the pixel electrodes affect the display quality and the TFT panel fabricated by the forgoing method has TFTs with good characteristics, but the display quality is not very good.

The present invention provides a new method of fabricating a panel of a flat display to mitigate or obviate the aforementioned problems, and the panel fabricated by the method has very good display quality.

### SUMMARY OF THE INVENTION

An objective of the present invention is to integrate fabrication of optical element film and semiconductor elements film on a panel of a flat display.

Another objective of the present invention is to provide a method of fabricating a panel of a flat display to efficiently increase display quality.

Other objectives, advantages and novel features of the invention will become more apparent from the following detailed description when taken in conjunction with the accompanying drawings.

### BRIEF DESCRIPTION OF THE DRAWINGS

FIGS. 1A to 1D are cross sectional side plan views of one portion of first embodiment of a TFT film with two substrates depicting the sequential states during the process of a TFT panel in accordance with the present invention;

FIG. 2 is a cross sectional side plan view of one portion of a second embodiment of a TFT film on a temporary substrate in accordance with the present invention;

FIG. 3 is a cross sectional side plan view of one portion of the first embodiment of the TFT film on a temporary substrate with a different optical element film in accordance with the present invention;

FIG. 4 is a cross sectional side plan view of one portion of the first embodiment of the TFT film on a substrate with an optical element film in accordance with the present invention; and

FIGS. 5A to 5D are cross sectional side plan views of a conventional TFT film with three substrates depicting the sequential states during a conventional process of bonding in accordance with the prior art.

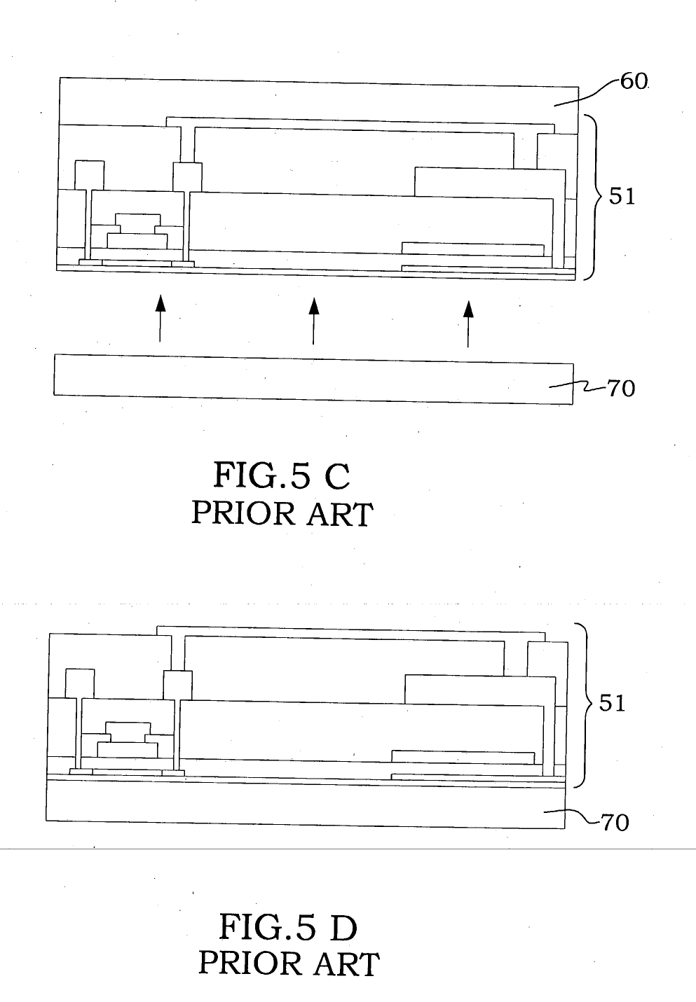

### DETAILED DESCRIPTION OF THE PREFERRED EMBODIMENT

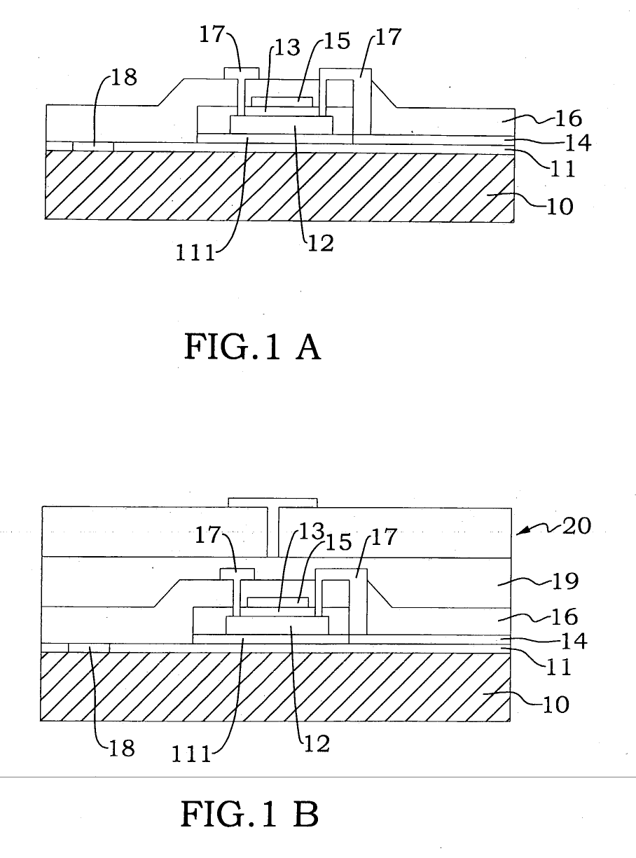

A method of fabricating a panel of a flat display in accordance with the present invention integrates a semiconductor element film and an optical element film. With reference to FIGS. 1A to 1D, a TFT panel of the flat display is an example to introduce the method including following steps.

In FIG. 1A, an etching stop layer (11) is formed on a temporary substrate (10). Preferably, the temporary substrate (10) can be heat-resistant material such as silicon, plastic, glass or quartz. The etching stop layer (11) can be silica, diamond or diamond-like carbon etc. The etching stop layer can be an alignment film.

In FIG. 1A, a buffer layer (111) is formed on the etching stop layer (11). The buffer layer (111) may be silicon material such as a transparent SiO₂ formed by deposition. Further, the buffer layer (111) is patterned to multiple portions on the etching stop layer (11).

In FIG. 1A, using photolithography, a semiconductor layer (12) is formed on part of each buffer layer (111). The semiconductor layer (12) served as a channel layer of a thin film transistor (TFT) may be a silicon (Si) layer formed by deposition.

In FIG. 1A, a gate oxide layer (13) is formed on the semiconductor layer (12), the buffer layer (111) and the etching stop layer (11). Further, the gate oxide layer (13) is patterned to flush with the buffer layer (111).

In FIG. 1A, using photolithography, a gate layer (15) is formed on part of the gate oxide layer (13) located on the semiconductor layer (12). The gate layer (15) may be a polysilicon layer, a metal layer or an alloy layer formed by deposition. Then using an ion implantation process, a source region and a drain region are formed in the semiconductor layer (12) on either side of the gate layer (15) to complete the TFT. Moreover, it is possible to form an LDD (lightly doped drain) structure in the source and drain regions. In order to simplify the illustration, the conventional LDD structure is not shown in FIGS. 1A to 1D, but is not intended to limit the present invention.

In FIG. 1A, using photolithography, pixel electrodes (14) are formed on parts of the etching stop layer (11) except other parts where the buffer layer (111) is formed. The pixel electrode (14) may be an indium tin oxide (ITO) layer formed by deposition.

In FIG. 1A, an inner layer (16) is covered on the gate layers (15), gate oxide layer (13) and pixel electrodes (14). Parts of the inner layer (16) and the gate oxide layer (13) are removed to form three first, second and third opening holes (not numbered). The first opening hole is exposed partial surface of the pixel electrodes (14), the second opening hole exposes partial surface of one side (drain region) the semiconductor layer (12) and the third opening hole exposes partial surface of the other side (source region) of the semiconductor film (12). Then, a conductive material such as tungsten (W), titanium (Ti) or aluminum (Al) etc. is filled in the first opening hole, the second opening hole and the third opening hole to form a first plug, a second plug and a third plug.

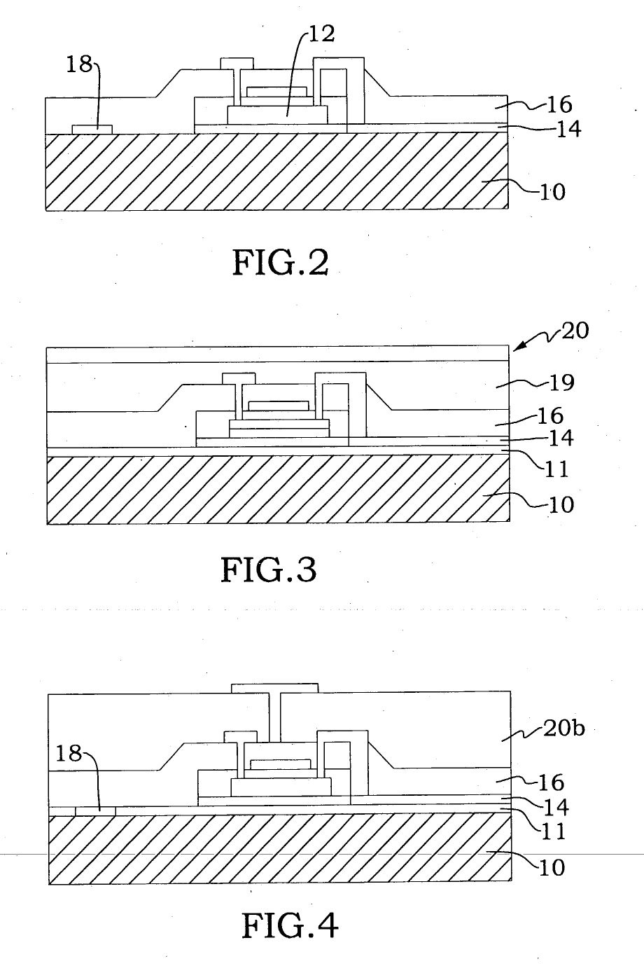

In FIG. 1B, a passivation layer (19) is formed on the entire inner layer (16) to provide a flat top face. An optical element film (20) on the flat top face of the passivation layer (19), wherein the optical element film (20) can be a color filter layer, a color transform layer (20a) (as shown in FIG. 3), a polarizing layer, a bright layer, a diffusive layer, etc.;

In FIG. 1C, a display panel (30) is bonded on the optical element film (20) by a specific bonding technique such as direct bonding, anodic bonding, low temperature bonding, intermediate bonding, adhesive bonding, laser melting bonding, etc.

In FIGS. 1C and 1D, the temporary substrate (10) is removed from the etching stop layer (11) by etching or CMP, grinding, lapping, polishing etc. techniques, wherein the etching stop layer (11) can protect the TFT film.

Further, the forgoing method includes a step of forming an exposed electrode (18) in the etching stop layer (11).

The etching stop layer (11) is not subjected to development and etching so the etching stop layer (11) has a flat top. Therefore, a bottom face (not numbered) of the pixel electrode (14) is also flat when the pixel electrode (14) formed on the etching stop layer (11).

The TFT film as described is fabricated on the temporary substrate (10) at a high temperature so the TFTs have good electrical characteristics. Besides, other semiconductor elements, such as metal oxide semiconductor (MOS), metal insulator metal capacitor (MIM), thin film diode (TFD) etc. are also formed on the temporary substrate (10) to have good electrical characteristics. In addition, the optical element film (20) can be directly fabricated on the TFT film can be specific optical element film (20) according to different applications, such as Liquid Crystal (LC), Organic Light Emitting Diodes (OLED), or Plastic Light Emitting Diodes (PLED). Therefore, the TFT film and the optical element film (20) can be integrated on the same panel (30).

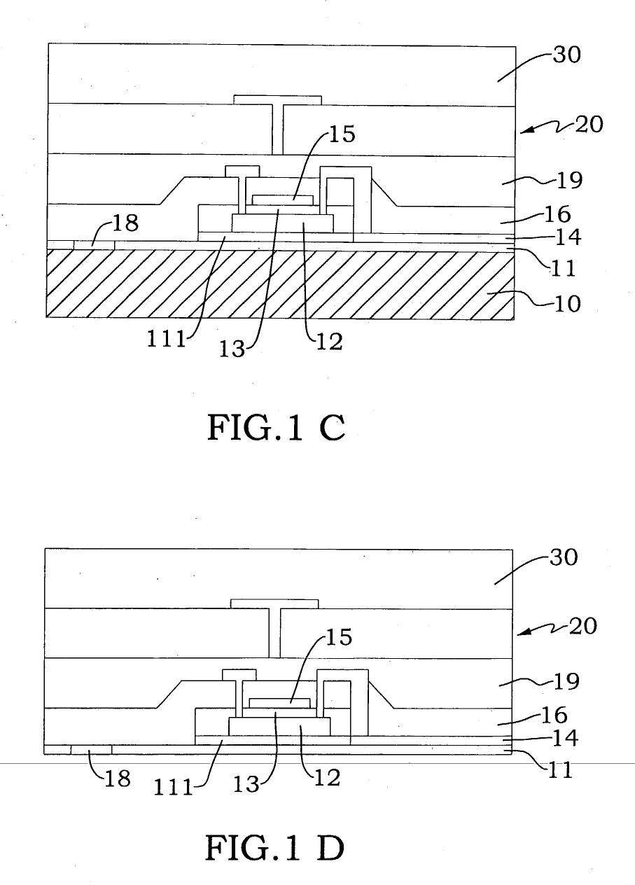

With reference to FIG. 2, a second preferred embodiment of the TFT film on the temporary substrate (10) has no the first protective (not shown) layer, so that the forgoing method has no the forming etching stop layer step. The buffer layer (111), the pixel electrode (14) and the exposed electrode (18) are formed on the temporary substrate (10). The TFT (not numbered) is formed on the buffer layer (111). When the temporary substrate (10) is removed, the pixel electrode (14) is directly exposed. An exposed face of the pixel electrode (14) is very flat, so the display quality can be increased.

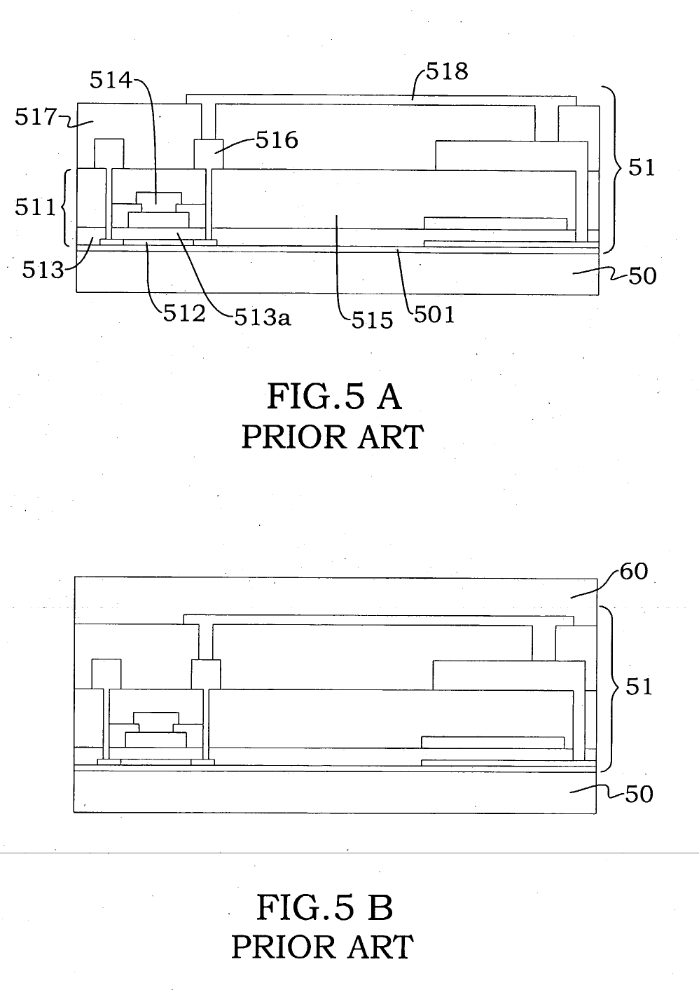

With reference to FIG. 4, another embodiment of a TFT panel without the display panel (not shown) is fabricated by the forgoing method without forming the passivation layer, so the optical element film (20) is formed on the insulating layer (16).

The TFT panel implemented by the method includes a display panel, an optical element film formed on the display panel and a TFT film on the optical element film. The TFT film is composed of facedown TFTs and pixel electrodes adjacent to the TFTs. The exposed face of the pixel electrode facing the temporary substrate is very flat because the pixel electrodes formed on one layer (etching stop layer) or on the temporary substrate.

In addition, the optical element film is also fabricated on the TFT film to simplify a complex aligning step for combining the optical element film and the TFT film and to increase aligning accuracy. Therefore, the present invention with one temporary substrate and a display panel provides a method and device to integrate the TFT film and the optical element film on a display panel to simplify the combining steps and to increase display quality.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method of fabricating a panel of a flat display comprising:
preparing a temporary substrate;
forming a semiconductor element film on the temporary substrate;
forming an optical element film on the semiconductor element film;
bonding a display panel on the optical element film; and
removing the temporary substrate to expose the pixel electrode;
whereby the panel of the flat display from top to bottom comprises a semiconductor element film a optical element film and the display panel.

2. The method as claimed in claim 1, the forming the semiconductor element film comprising:
forming semiconductor elements on the temporary substrate;
forming pixel electrodes on the temporary substrate adjacent to the semiconductor elements; and
covering the semiconductor elements and the pixel electrodes with an inner layer to provide a flat top face, wherein the optical element film is formed on the inner layer.

3. The method as claimed in claim 2, wherein the semiconductor elements are thin film transistors (TFTs) and forming a TFT comprises steps of
forming an etching stop layer on the temporary substrate;
forming a semiconducting film on the etching stop layer to define a drain, a source and an active region;
forming a gate oxide layer on the semiconducting film to complete a TFT;
forming a first metal layer on the gate oxide layer, wherein the first metal layer is covered by the inner layer; and
forming a second metal layer through the inner layer and the gate oxide layer to connect to the pixel electrode to the semiconducting layer and to connect adjacent TFTs.

4. The method as claimed in claim 3, wherein before the step forming facedown thin film transistors, the temporary substrate is first covered with a buffer layer.

5. The method as claimed in claim 4, wherein after the step covering the temporary substrate with an inner layer, the inner layer with the second metal layer is covered with a passivation layer, wherein the optical elements are formed on the passivation layer.

6. The method as claimed in claim 3, wherein after covering the temporary substrate with the etching stop layer, the method further comprises forming exposed electrodes in the etching stop layer.

7. The method as claimed in claim 2, wherein before the step forming semiconductor elements, the method further comprises a forming exposed electrodes on the temporary substrate.

8. The method as claimed in claim 1, wherein the optical element film is a color transform layer, a color filter layer, a polarizing layer, a bright layer or a diffusive layer.

9. The method as claimed in claim 1, wherein the specific bonding technique is directing bonding, anodic bonding, low temperature bonding, intermediate boning, adhesive bonding or laser melting bonding.

10. The method as claimed in claim 2, each semiconductor element is adapted to be a metal oxide semiconductor (MOS), a metal insulator metal capacitor (MIM) or a thin film diode (TFD).

11. A panel of a flat display, comprising
a display panel having a top face;
an optical element film formed on the top face of the display panel; and
a semiconductor element film formed on the optical element film;
whereby the panel from top to bottom comprises the semiconductor element film, the optical element film and the display panel.

12. The panel of the flat display as claimed in claim 11, the semiconductor element film from bottom to top comprises:
an inner layer with a second metal layer;
multiple semiconductor elements formed on the inner layer; and
multiple pixel electrodes around the semiconductor elements formed on the inner layer, wherein each pixel electrode has a flat exposed face and is connected to the semiconductor elements by the second metal layer.

13. The panel of the flat display as claimed in claim 12, wherein each semiconductor element is facedown thin film transistor wherein each facedown thin film transistor from top to bottom comprises:
a buffer layer;
a semiconducting film for defining a source, a drain and an active region; and
a gate oxide layer, wherein a first metal line is formed on the gate oxide layer.

14. The panel of the flat display as claimed in claim 12, further comprises an etching stop layer is covered on semiconductor elements and the pixel electrodes.

15. The panel of the flat display as claimed in claim 12, further comprises a passivation layer is formed between the inner layer and the optical element film.

16. The panel of the flat display as claimed in claim 11, the optical element film is a color transform layer, a color filter layer, a polarizing layer, a bright layer or a diffusive layer.

17. The panel of the flat display as claimed in claim 12, each semiconductor element is adapted to be a metal oxide semiconductor (MOS), a metal insulator metal capacitor (MIM) or a thin film diode (TFD).
